(19) United States
(12) Patent Application Publication
(10) Pub. No.: US 2026/0018212 A1
(43) Pub. Date: Jan. 15, 2026

(54) IMPLEMENTING MEMORY DEVICE PROGRAM INHIBIT OPERATIONS WITH TARGET LEVEL SELECTION

(71) Applicant: MICRON TECHNOLOGY, INC., Boise, ID (US)

(72) Inventors: Jisuk Kim, San Jose, CA (US); Taehyun Kim, San Jose, CA (US); Dong Kyo Shim, Milpitas, CA (US)

(21) Appl. No.: 19/256,599

(22) Filed: Jul. 1, 2025

Related U.S. Application Data
(60) Provisional application No. 63/671,401, filed on Jul. 15, 2024.

(51) Int. Cl. G11C 16/10

(52) U.S. Cl. CPC G11C 16/10

(57) ABSTRACT

A memory device includes a memory array and control logic, operatively coupled with the memory array, to perform operations including selecting a first group of bitlines of the memory array, the first group of bitlines corresponding to target program levels to be programmed during a program loop, selecting a second group of bitlines of the memory array, the second group of bitlines corresponding to program levels that are to be inhibited during the program loop, causing an inhibit bias voltage to be applied to the second group of bitlines, and causing a ground voltage to be applied to program the first group of bitlines during the first program loop. The second group of bitlines includes at least one bitline corresponding to a program level that has not been programmed.

The present application claims the benefit of U.S. Provisional Patent Application No. 63/671,401, filed on Jul. 15, 2024, the entire contents of which are hereby incorporated by reference herein.

### TECHNICAL FIELD

### Technical Field

Embodiments of the disclosure relate generally to memory sub-systems, and more specifically, relate to implementing memory device program inhibit operations with target level selection.

### Background

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding only.

FIG. 1A illustrates an example computing system that includes a memory sub-system in accordance with some embodiments of the present disclosure.

FIG. 1B illustrates an example block diagram of a memory device in communication with a memory sub-system controller of a memory sub-system, in accordance with some embodiments of the present disclosure.

FIGS. 2A-2C are diagrams of portions of an example array of memory cells included in a memory device, in accordance with some embodiments of the present disclosure.

FIG. 3A is a diagram of an example system for implementing memory device program inhibit operations with target level selection, in accordance with some embodiments of the present disclosure.

FIG. 3B is a diagram of an example page buffer unit of a system for implementing memory device program inhibit operations with target level selection, in accordance with some embodiments of the present disclosure.

FIG. 4 is as diagram illustrating an example of implementing memory device program inhibit operations with target level selection, in accordance with some embodiments of the present disclosure.

FIG. 5 is a flow diagram of a method to implementing memory device program inhibit operations with target level selection, in accordance with some embodiments of the present disclosure.

FIG. 6 is a block diagram of an example computer system in which embodiments of the present disclosure may operate.

### DETAILED DESCRIPTION

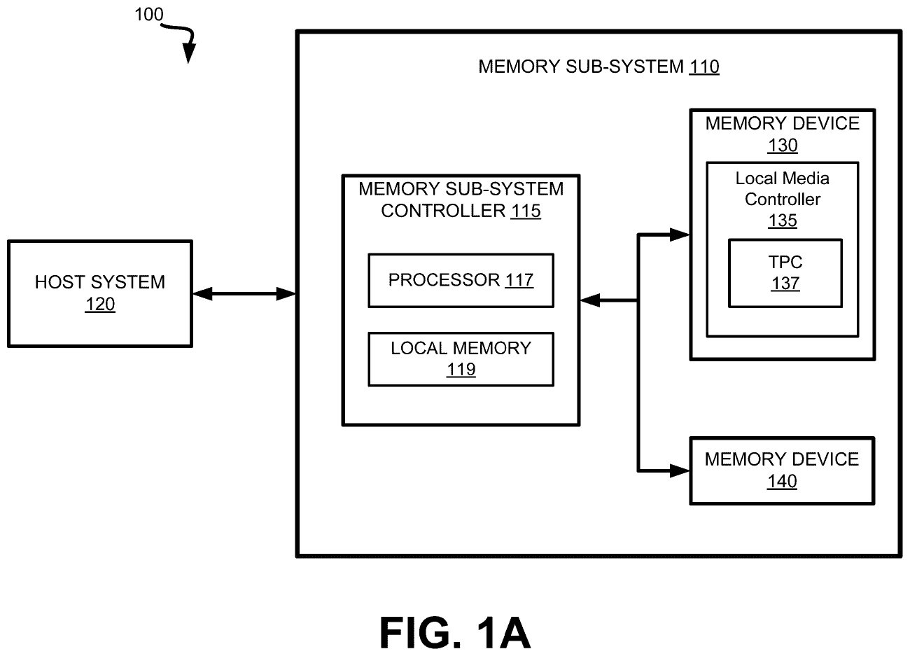

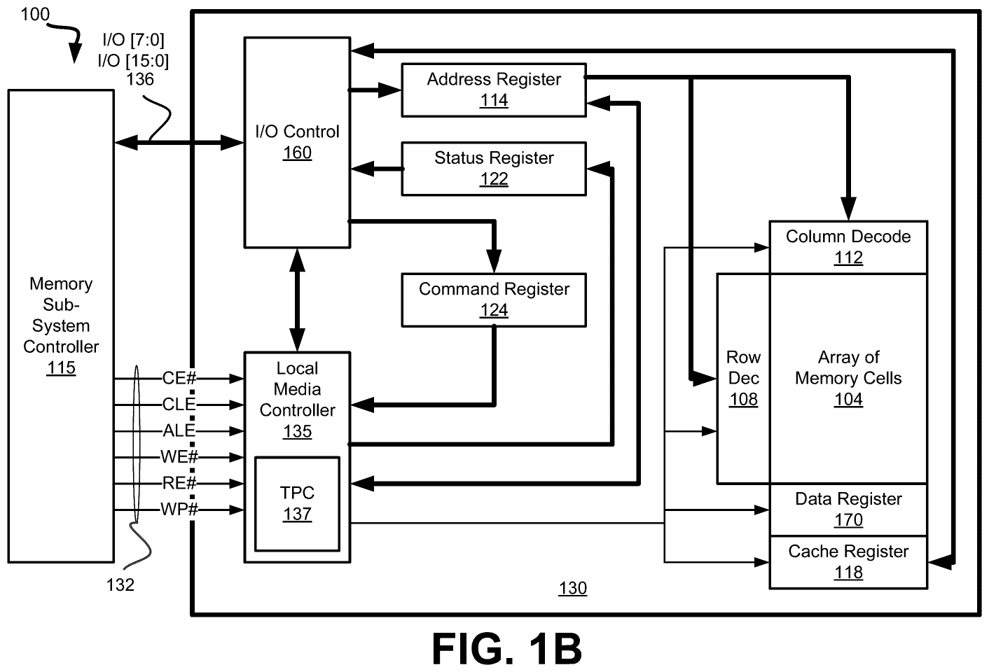

Aspects of the present disclosure are directed to implementing memory device program inhibit operations with target level selection. A memory sub-system can be a storage device, a memory module, or a combination of a storage device and memory module. Examples of storage devices and memory modules are described below in conjunction with FIG. 1A. In general, a host system can utilize a memory sub-system that includes one or more components, such as memory devices that store data. The host system can provide data to be stored at the memory sub-system and can request data to be retrieved from the memory sub-system.

A memory sub-system can include high density non-volatile memory devices where retention of data is desired when no power is supplied to the memory device. One example of non-volatile memory devices is a not-and (NAND) memory device. Other examples of non-volatile memory devices are described below in conjunction with FIG. 1A. A non-volatile memory device is a package of one or more dies. Each die can include one or more planes. For some types of non-volatile memory devices (e.g., NAND devices), each plane includes of a set of physical blocks. Each block includes of a set of pages. Each page includes of a set of memory cells (“cells”). A cell is an electronic circuit that stores information. Depending on the cell type, a cell can store one or more bits of binary information, and has various logic states that correlate to the number of bits being stored. The logic states can be represented by binary values, such as “0” and “1,” or combinations of such values.

A memory device can be arranged in a two-dimensional or a three-dimensional grid. Memory cells are formed onto a silicon wafer in an array of A wordline can have a row of associated memory cells in a memory device that are used with one or more bitlines to generate the address of each of the memory cells. The intersection of a bitline and wordline constitutes the address of the memory cell. A block hereinafter refers to a unit of the memory device used to store data and can include a group of memory cells, a wordline group, a wordline, or individual memory cells. One or more blocks can be grouped together to form separate partitions (e.g., planes) of the memory device in order to allow concurrent operations to take place on each plane. A block of data can correspond to one or more data addresses in the memory device (e.g., a block, a plurality of blocks, a plurality of cells, etc.). The memory device can include circuitry that performs concurrent memory page accesses of two or more memory planes. For example, the memory device can include multiple access line driver circuits and power circuits that can be shared by the planes of the memory device to facilitate concurrent access of pages of two or more memory planes, including different page types. For ease of description, these circuits can be generally referred to as independent plane driver circuits. Depending on the storage architecture employed, data can be stored across the memory planes (i.e., in stripes). Accordingly, one request to read a block of data can result in read operations performed on two or more of the memory planes of the memory device.

A memory cell (“cell”) can be programmed (written to) by applying a certain voltage to the memory cell, which results in an electric charge being held by the cell. For example, a voltage signal V_{CG} that can be applied to a control electrode of the cell to open the cell to the flow of electric current across the cell, between a source electrode and a drain electrode. More specifically, for each individual memory cell (having a charge Q stored thereon) there can be a threshold control gate voltage V_{T} (herein also referred to as the “threshold voltage” or simply as “threshold”) such that the source-drain electric current is low for the control gate voltage (V_{CG}) being below the threshold voltage, V_{CG}<V_{T}. The current increases substantially once the control gate voltage has exceeded the threshold voltage, V_{CG}>V_{T}. Because the actual geometry of the electrodes and gates varies from cell to cell, the threshold voltages can be different even for cells implemented on the same die. The memory cells can, therefore, be characterized by a distribution P of the threshold voltages, P(Q,V_{T})=dW/dV_{T}, where dW represents the probability that any given cell has its threshold voltage within the interval [V_{T}, V_{T}+dV_{T}] when charge Q is placed on the cell.

A memory device can have distributions P(Q,V_{T}) that are narrow compared with the working range of control voltages tolerated by the cells of the device. Accordingly, multiple non-overlapping distributions P(Qₖ, V_{T}) (“valleys”) can be fit into the working range allowing for storage and reliable detection of multiple values of the charge Qₖ, k=1, 2, 3 . . . . The distributions (valleys) are interspersed with voltage intervals (“valley margins”) where none (or very few) of the memory cells of the device have their threshold voltages. Such valley margins can, therefore, be used to separate various charge states Qₖ—the logical state of the cell can be determined by detecting, during a read operation, between which two valley margins the respective threshold voltage V_{T} of the cell resides. Specifically, the read operation can be performed by comparing the measured threshold voltage V_{T} exhibited by the memory cell to one or more reference voltage levels corresponding to known valley margins (e.g., centers of the margins) of the memory device. One type of memory cell (“cell”) is a single level cell (SLC), which stores 1 bit per cell and defines 2 logical states (“states”) (“1” or “L0” and “0” or “L1”) each corresponding to a respective V_{T} level. For example, the “1” state can be an erased state and the “0” state can be a programmed state (L1). Another type of cell is a multi-level cell (MLC), which stores 2 bits per cell and defines 4 states (“11” or “L0”, “10” or “L1”, “01” or “L2” and “00” or “L3”) each corresponding to a respective V_{T} level. For example, the “11” state can be an erased state and the “01”, “10” and “00” states can each be a respective programmed state. Another type of cell is a triple level cell (TLC), which stores 3 bits per cell and defines 8 states (“111” or “L0”, “110” or “L1”, “101” or “L2”, “100” or “L3”, “011” or “L4”, “010” or “L5”, “001” or “L6”, and “000” or “L7”) each corresponding to a respective V_{T} level. For example, the “111” state can be an erased state and each of the other states can be a respective programmed state. Another type of a cell is a quad-level cell (QLC), which stores 4 bits per cell and defines 16 states L0-L15, where L0 corresponds to “1111” and L15 corresponds to “0000”. Another type of cell is a penta-level cell (PLC), which stores 5 bits per cell and defines 32 states. Other types of cells are also contemplated. Thus, an n-level cell can use 2ⁿ levels of charge to store n bits. A memory device can include one or more arrays of memory cells such as SLCs, MLCs, TLCs, QLCs, PLCs, etc. or any combination of such. For example, a memory device can include an SLC portion, and an MLC portion, a TLC portion, a QLC portion, or a PLC portion of memory cells.

A valley margin can also be referred to as a read window. For example, in a SLC cell, there is 1 read window that exists with respect to the 2 V_{T} distributions. As another example, in an MLC cell, there are 3 read windows that exist with respect to the 4 V_{T} distributions. As yet another example, in a TLC cell, there are 7 read windows that exist with respect to the 8 V_{T} distributions. Read window size generally decreases as the number of states represented by the V_{T} distributions increases. For example, the 1 read window for the SLC cell can be larger than each of the 3 read windows for the MLC cell, and each of the 3 read windows for the MLC cell can be larger than each of the 7 read windows for the TLC cell etc. Read window budget (RWB) refers to the cumulative value of the read windows.

In some memory devices (e.g., NAND flash memory devices), all unprogrammed cells are targeted to be programmed. For some memory devices, such as QLC memory devices, a program operation to program the memory cells associated with a wordline can include a coarse program suboperation used to generate a coarse program distribution for cells connected to the wordline, and a fine program suboperation to generate a fine program distribution for the cells connected to the wordline. To illustrate, for a set of wordlines, the memory cells associated with a first wordline of the set of wordlines can be programmed using the coarse program suboperation to generate a first coarse program distribution, and the memory cells associated with a second wordline of the set of wordlines can be programmed using the coarse program suboperation to generate a second coarse program distribution. After generating the second coarse program distribution, the memory cells associated with the first wordline can be programmed using the fine program suboperation to generate a first fine program distribution. After generating the first fine program distribution, the memory cells associated with a third wordline of the set of wordlines can be programmed using the coarse program suboperation to generate a third coarse program distribution. After generating the third coarse program distribution, the memory cells associated with the second wordline can be programmed using the fine program suboperation to generate a second fine program distribution. Such an alternating process between coarse and fine program suboperations can be performed until each wordline of the set of wordlines is programmed.

When a cell has reached a target program level, the cell can be placed in an inhibit state so that other cells can be programmed. A program inhibit operation can be performed to cause a cell to be placed in the inhibit state. More specifically, an inhibit bias voltage can be applied to a bitline connected to a first set of cells to place the first set of cells in the inhibit state, and a ground voltage can be applied to another bitline connected to a second set of cells to program the second set of cells. The inhibit bias voltage has a magnitude that, when applied to an initial memory cell connected to the bitline (e.g., the source of the transistor of the initial memory cell), causes the channel defined by the memory cells connected to the bitline to float.

Multiple program loops can be used to program cells to respective target levels. Each program loop can include, a program inhibit operation to inhibit first cells connected to a first set of bitlines, and a program operation (e.g., coarse program suboperation and fine program suboperation) to program second cells connected to a second set of bitlines by applying a ground voltage. For example, a first or initial program loop can be used to program a first set of cells to a first program level (L1), a second program loop can be used to program a second set of cells to a second program level (L2), a third program loop can be used to program a third set of cells to a third program level (L3), etc.

Typically, only cells that have reached their target levels are inhibited during a program loop. To illustrate, during the first program loop described above, an inhibit bias voltage is applied only to the erase level (L0) cell-connected bitline during the program inhibit operation, while a program voltage is applied to the remaining bitlines to program the first set of cells to L1. In the second program loop described above, the inhibit bias voltage is applied only to the L0 cell-connected bitline and the L1 cell-connected bitline, while a program voltage is applied to the remaining bitlines to program the second set of cells to L2. In the third program loop, the inhibit bias voltage is applied only to the L0 cell-connected bitline, the L1 cell-connected bitline, and the L2 cell-connected bitline, while a program voltage is applied to the remaining bitlines to program the third set of cells to L3. Once each target level has been achieved during the last program loop (e.g., L15 in the case of QLC), the program operation can end.

In the typical implementation described above, the number of bitlines to which the inhibit bias voltage is applied to increases by one after each program loop (e.g., the number of bitlines to which the inhibit bias voltage is applied does not stay constant across program loops). The changes in the number of bitlines to which the inhibit bias voltage is applied can cause a variation in bitline-to-bitline coupling capacitance. The variation in bitline-to-bitline coupling capacitance can result in peak current variation. For example, the peak current can be strongest when the inhibit bias voltage is applied to approximately half of the bitlines. Additionally, the variation in bitline-to-bitline coupling capacitance can cause channel-to-wordline coupling variation, which in turn can affect wordline setup time.

Aspects of the present disclosure address the above and other deficiencies by implementing memory device program inhibit operations with target level selection. Embodiments described herein can be used to maintain the number of bitlines to which the inhibiting bias is applied, as approximately constant across each program loop. To do so, for each program loop, a local media controller can select a (proper) subset of program levels of the set of remaining program levels to be programmed, instead of the entire set of remaining program levels to be programmed. The subset of program levels can include a number of consecutive program levels. More specifically, the local media controller can cause the inhibit bias voltage to be applied to each bitline that does not correspond to the subset of program levels, and then apply the ground voltage to each bitline that corresponds to the subset of program levels.

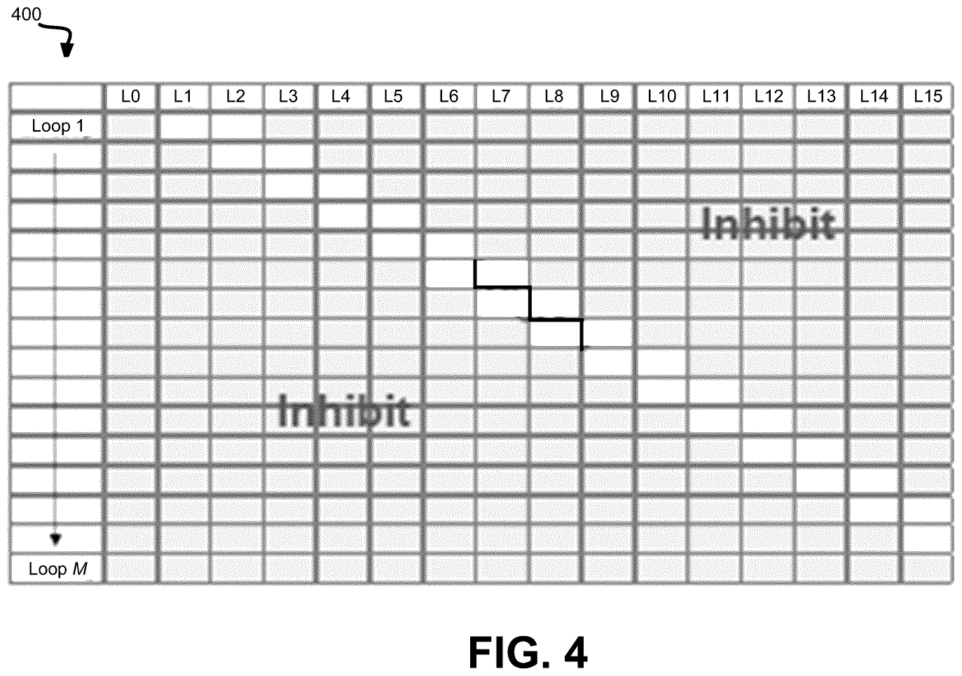

The number of consecutive program levels of the subset of program levels (i.e., the cardinality of the subset of program levels) can be less than or equal to a maximum number of program levels that can be programmed during a program loop, where the maximum number of program levels that can be programmed during the program loop is less than the total number of remaining program levels to be programmed (i.e., the cardinality of the set of remaining program levels). Visually, the subsets across the program loops illustrate a diagonal programming “band” surrounded by inhibited levels. An example of this is described below with reference to FIG. 4.

As an illustrative example, for a QLC device having 16 levels including erase level L0 and program levels L1-15, assume that the maximum number of program levels that can be programmed during the program loop is two. During the first program loop, levels L1 and L2 can be programmed together, while an inhibit bias voltage can be applied to the bitlines corresponding to levels L0 and L3-L15. During the second program loop, levels L2 and L3 can be programmed together, while an inhibit bias voltage is applied to the bitlines corresponding to levels L0, L1 and L4-L15. During the third program loop, levels L3 and LA can be programmed together, while an inhibit bias voltage is applied to the bitlines corresponding to levels L0, L1, L2, and L5-L15. A similar process can continue until the last final program loop. Thus, the number of inhibited bitlines remains approximately constant from the first program loop to the last program loop.

In a typical implementation in which only cells that have reached their target levels are inhibited during a program loop, there are two groups of bitlines to track across program loops. In particular, for each program loop, there is a group of bitlines to be inhibited corresponding to cells that have reached the target program level prior to the program loop, and a group of bitlines to be programmed corresponding to cells that have yet to reach the target program level.

In contrast, there are three groups of bitlines to track in accordance with embodiments described herein. In particular, for each program loop, there is a first group of bitlines to be inhibited corresponding to cells that have reached their target program levels prior to the program loop, a group of bitlines to be programmed corresponding to cells with target program levels included in the subset of program levels of the set of remaining program levels to be programmed during the program loop, and a second group of bitlines to be inhibited corresponding to cells that with target program levels within the set of remaining program levels that are not included in the subset.

Embodiments described herein can use page buffers to track the three groups of bitlines through the program loops. For example, a page buffer can include a set of latches (e.g., sensing (SA) latch, data latch, and cache latch). The set of latches can store information (e.g., bit values) regarding programmed cells, unprogrammed cells that are not being targeted for program during a program loop, and unprogrammed cells that are being targeted for programming during the program loop. have and/or have not been programmed. Before inhibit biasing during the program loop, the page buffer can select the programmed cells and the unprogrammed cells that are not being targeted for programming during the program loop.

Advantages of the present disclosure include, but are not limited to, reduced peak current during a program operation, reduced bitline-to-bitline channel coupling, and improved wordline setup time. For example, embodiments described herein can be used to eliminate scenarios in which the inhibit bias voltage is applied to approximately half of the bitlines.

FIG. 1A illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a combination of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to multiple memory sub-systems 110 of different types. FIG. 1A illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can be coupled to the memory sub-system 110 via a physical host interface. Examples of a physical host interface include, but are not limited to, a serial advanced technology attachment (SATA) interface, a compute express link (CXL) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access components (e.g., memory devices 130) when the memory sub-system 110 is coupled with the host system 120 by the physical host interface (e.g., PCIe bus or CXL bus). The physical host interface can provide an interface for passing control, address, data, and other signals between the memory sub-system 110 and the host system 120. FIG. 1A illustrates a memory sub-system 110 as an example. In general, the host system 120 can access multiple memory sub-systems via a same communication connection, multiple separate communication connections, and/or a combination of communication connections.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller, CXL controller). The host system 120 uses the memory sub-system 110, for example, to program data to the memory sub-system 110 and read data from the memory sub-system 110.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include a not-and (NAND) type flash memory and write-in-place memory, such as a three-dimensional cross-point (“3D cross-point”) memory device, which is a cross-point array of non-volatile memory cells. A cross-point array of non-volatile memory cells can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130 can include one or more arrays of memory cells. One type of memory cell, for example, single level cells (SLC) can store one bit per cell. Other types of memory cells, such as multi-level cells (MLCs), triple level cells (TLCs), quad-level cells (QLCs), and penta-level cells (PLCs) can store multiple bits per cell. In some embodiments, each of the memory devices 130 can include one or more arrays of memory cells such as SLCs, MLCs, TLCs, QLCs, PLCs or any combination of such. In some embodiments, a particular memory device can include an SLC portion, and an MLC portion, a TLC portion, a QLC portion, or a PLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), not-or (NOR) flash memory, or electrically erasable programmable read-only memory (EEPROM).

A memory sub-system controller 115 can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processing device, which includes one or more processors (e.g., processor 117), configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the memory sub-system 110 in FIG. 1 has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical address (e.g., a logical block address (LBA), namespace) and a physical address (e.g., physical block address) that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some embodiments, the memory devices 130 include local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, memory sub-system 110 is a managed memory device, which is a raw memory device having control logic (e.g., local media controller 135) on the die and a controller (e.g., memory sub-system controller 115) for media management within the same memory device package. An example of a managed memory device is a managed NAND (MNAND) device.

The memory sub-system 110 includes targeted programming component (TPC) 137 that can implement memory device program inhibit operations with target level selection. In some embodiments, local media controller 135 includes at least a portion of TPC 137 and is configured to perform the functionality described herein. In some embodiments, the memory sub-system controller 115 includes at least a portion of TPC 137. In some embodiments, TPC 137 is part of the host system 120, an application, or an operating system. Further details regarding TPC 137 and the operations supported by TPC 137 will be described below with reference to FIGS. 1B-6.

FIG. 1B illustrates an example simplified block diagram of a first apparatus, in the form of a memory device 130, in communication with a second apparatus, in the form of a memory sub-system controller 115 of a memory sub-system (e.g., memory sub-system 110 of FIG. 1A), according to an embodiment. Some examples of electronic systems include personal computers, personal digital assistants (PDAs), digital cameras, digital media players, digital recorders, games, appliances, vehicles, wireless devices, mobile telephones and the like. The memory sub-system controller 115 (e.g., a controller external to the memory device 130), can be a memory controller or other external host device. The memory sub-system controller 115 can include the TPC 137.

Memory device 130 includes an array of memory cells 104 logically arranged in rows and columns. Memory cells of a logical row are typically connected to the same access line (e.g., a wordline) while memory cells of a logical column are typically selectively connected to the same data line (e.g., a bit line). A single access line can be associated with more than one logical row of memory cells and a single data line can be associated with more than one logical column. Memory cells (not shown in FIG. 1B) of at least a portion of array of memory cells 104 are capable of being programmed to one of at least two target data states. In one embodiment, the array of memory cells 104 (i.e., a “memory array”) can include a number of sacrificial memory cells used to detect the occurrence of read disturb in memory device 130, as described in detail herein.

Row decode circuitry 108 and column decode circuitry 109 are provided to decode address signals. Address signals are received and decoded to access the array of memory cells 104. Memory device 130 also includes input/output (I/O) control circuitry 160 to manage input of commands, addresses and data to the memory device 130 as well as output of data and status information from the memory device 130. An address register 114 is in communication with I/O control circuitry 160 and row decode circuitry 108 and column decode circuitry 109 to latch the address signals prior to decoding. A command register 124 is in communication with I/O control circuitry 160 and local media controller 135 to latch incoming commands.

A controller (e.g., the local media controller 135 internal to the memory device 130) controls access to the array of memory cells 104 in response to the commands and generates status information for the external memory sub-system controller 115, i.e., the local media controller 135 is configured to perform access operations (e.g., read operations, program operations and/or erase operations) on the array of memory cells 104. The local media controller 135 is in communication with row decode circuitry 108 and column decode circuitry 109 to control the row decode circuitry 108 and column decode circuitry 109 in response to the addresses.

The local media controller 135 is also in communication with a cache register 172. Cache register 172 latches data, either incoming or outgoing, as directed by the local media controller 135 to temporarily store data while the array of memory cells 104 is busy writing or reading, respectively, other data. During a program operation (e.g., write operation), data can be passed from the cache register 172 to the data register 170 for transfer to the array of memory cells 104; then new data can be latched in the cache register 172 from the I/O control circuitry 160. During a read operation, data can be passed from the cache register 172 to the I/O control circuitry 160 for output to the memory sub-system controller 115; then new data can be passed from the data register 170 to the cache register 172. The cache register 172 and/or the data register 170 can form (e.g., can form a portion of) a page buffer of the memory device 130. A page buffer can further include sensing devices (not shown in FIG. 1B) to sense a data state of a memory cell of the array of memory cells 104, e.g., by sensing a state of a data line connected to that memory cell. A status register 122 can be in communication with I/O control circuitry 160 and the local memory controller 135 to latch the status information for output to the memory sub-system controller 115.

Memory device 130 receives control signals at the memory sub-system controller 115 from the local media controller 135 over a control link 132. For example, the control signals can include a chip enable signal CE #, a command latch enable signal CLE, an address latch enable signal ALE, a write enable signal WE #, a read enable signal RE #, and a write protect signal WP #. Additional or alternative control signals (not shown) can be further received over control link 132 depending upon the nature of the memory device 130. In one embodiment, memory device 130 receives command signals (which represent commands), address signals (which represent addresses), and data signals (which represent data) from the memory sub-system controller 115 over a multiplexed input/output (I/O) bus 134 and outputs data to the memory sub-system controller 115 over I/O bus 134.

For example, the commands can be received over input/output (I/O) pins [7:0] of I/O bus 134 at I/O control circuitry 160 and can then be written into command register 124. The addresses can be received over input/output (I/O) pins [7:0] of I/O bus 134 at I/O control circuitry 160 and can then be written into address register 114. The data can be received over input/output (I/O) pins [7:0] for an 8-bit device or input/output (I/O) pins [15:0] for a 16-bit device at I/O control circuitry 160 and then can be written into cache register 172. The data can be subsequently written into data register 170 for programming the array of memory cells 104.

In an embodiment, cache register 172 can be omitted, and the data can be written directly into data register 170. Data can also be output over input/output (I/O) pins [7:0] for an 8-bit device or input/output (I/O) pins [15:0] for a 16-bit device. Although reference can be made to I/O pins, they can include any conductive node providing for electrical connection to the memory device 130 by an external device (e.g., the memory sub-system controller 115), such as conductive pads or conductive bumps as are commonly used.

It will be appreciated by those skilled in the art that additional circuitry and signals can be provided, and that the memory device 130 of FIG. 1B has been simplified. It should be recognized that the functionality of the various block components described with reference to FIG. 1B can not necessarily be segregated to distinct components or component portions of an integrated circuit device. For example, a single component or component portion of an integrated circuit device could be adapted to perform the functionality of more than one block component of FIG. 1B. Alternatively, one or more components or component portions of an integrated circuit device could be combined to perform the functionality of a single block component of FIG. 1B. Additionally, while specific I/O pins are described in accordance with popular conventions for receipt and output of the various signals, it is noted that other combinations or numbers of I/O pins (or other I/O node structures) can be used in the various embodiments.

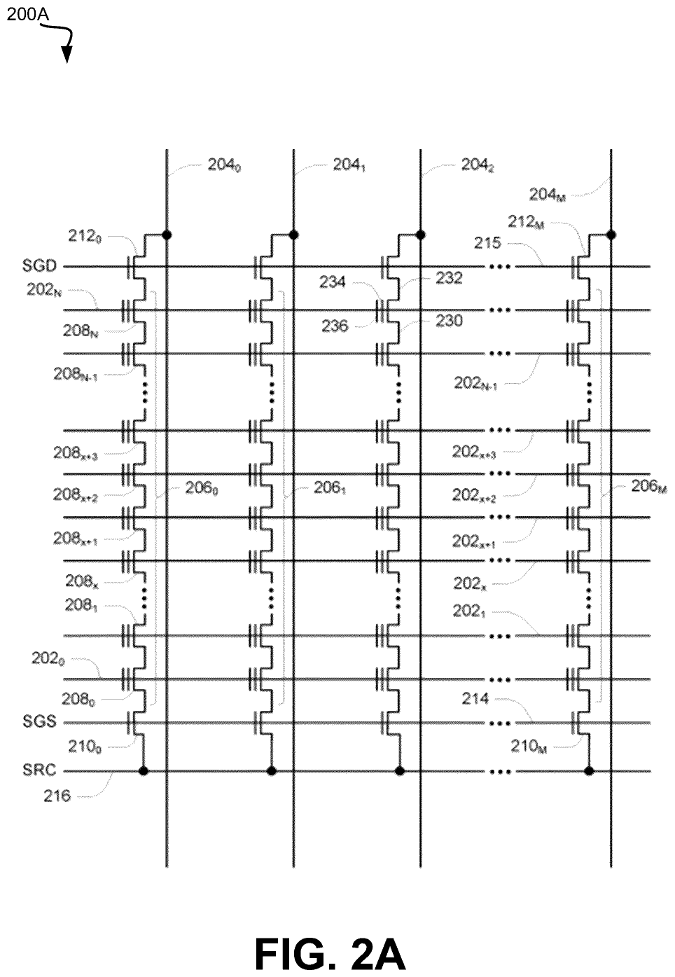

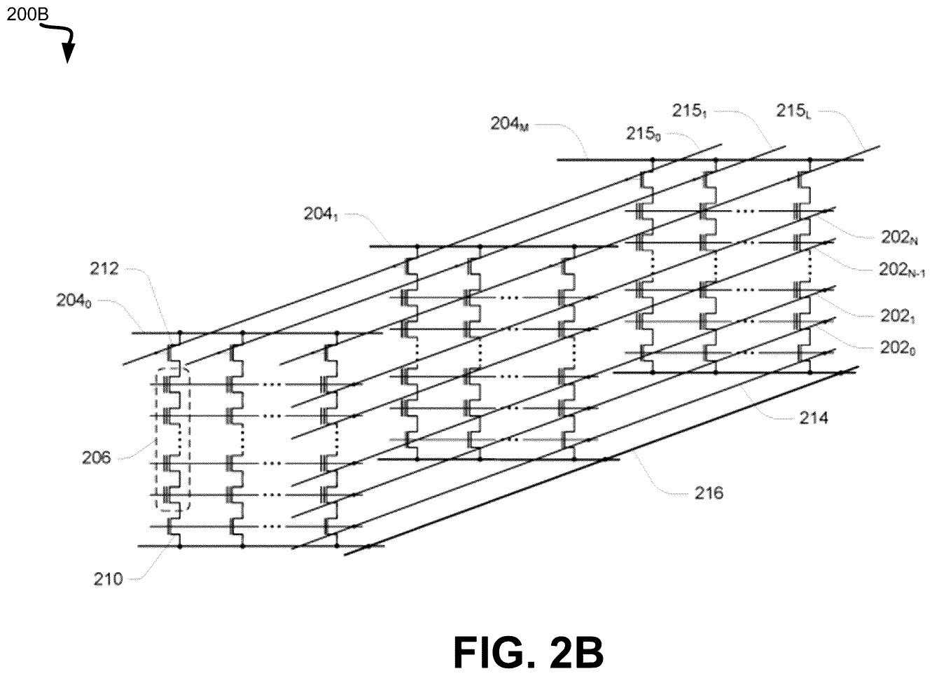

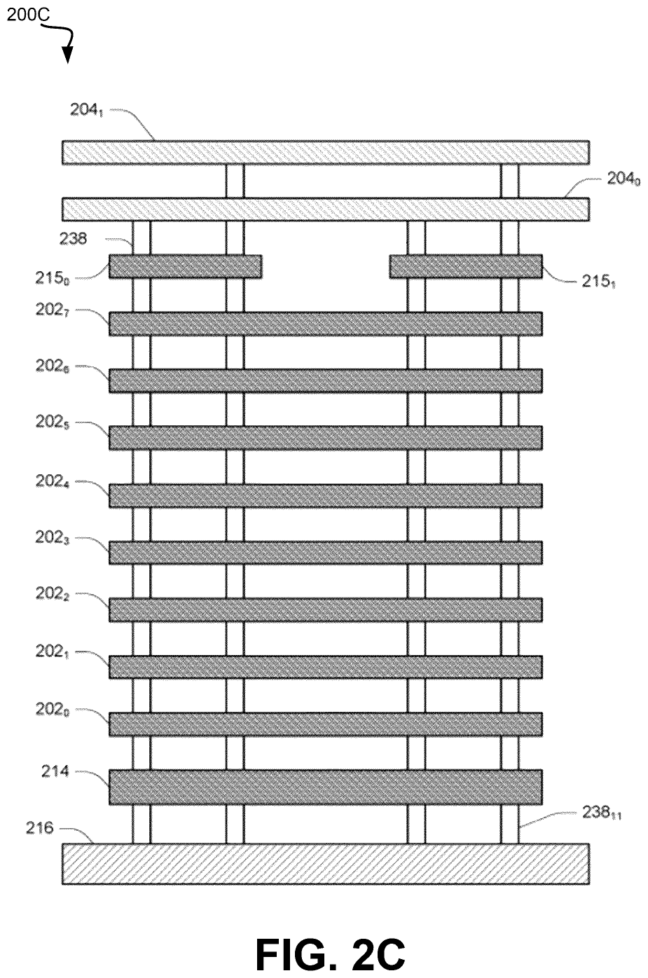

FIGS. 2A-2C are diagrams of portions of an example array of memory cells included in a memory device, in accordance with some embodiments of the present disclosure. For example, FIG. 2A is a schematic of a portion of an array of memory cells (“memory array”) 200A as could be used in a memory device (e.g., as a portion of array of memory cells 104). Memory array 200A includes access lines, such as wordlines 202₀ to 202_{N}, and a data line, such as bitline 204. The wordlines 202 may be connected to global access lines (e.g., global wordlines), not shown in FIG. 2A, in a many-to-one relationship. For some embodiments, memory array 200A may be formed over a semiconductor that, for example, may be conductively doped to have a conductivity type, such as a p-type conductivity, e.g., to form a p-well, or an n-type conductivity, e.g., to form an n-well.

Memory array 200A can be arranged in rows each corresponding to a respective wordline 202 and columns each corresponding to a respective bitline 204. Rows of memory cells 208 can be divided into one or more groups of physical pages of memory cells 208, and physical pages of memory cells 208 can include every other memory cell commonly addressable by a given wordline 202. For example, memory cells 208 commonly addressable by wordline 202_{N} and selectively connected to even bitlines 204 (e.g., bitlines 204₀, 204₂, 204₄, etc.) may be one physical page of memory cells 208 (e.g., even memory cells) while memory cells 208 commonly addressable by wordline 202_{N} and selectively connected to odd bitlines 204 (e.g., bitlines 204₁, 204₃, 204₅, etc.) may be another physical page of memory cells 208 (e.g., odd memory cells). Although bitlines 204₃-204₅ are not explicitly depicted in FIG. 2A, it is apparent from the figure that the bitlines 204 of the memory array 200A may be numbered consecutively from bitline 204₀ to bitline 204_{M}. Other groupings of memory cells 208 commonly addressable by a given wordline 202 may also define a physical page of memory cells 208. For certain memory devices, all memory cells commonly addressable by a given wordline might be deemed a physical page of memory cells. The portion of a physical page of memory cells (which, in some embodiments, could still be the entire row) that is read during a single read operation or programmed during a single program operation (e.g., an upper or lower page of memory cells) might be deemed a logical page of memory cells. A block of memory cells may include those memory cells that are configured to be erased together, such as all memory cells addressable by wordlines 202₀-202_{N} (e.g., all strings 206 sharing common wordlines 202). Unless expressly distinguished, a reference to a page of memory cells herein refers to the memory cells of a logical page of memory cells.

Each column can include a string of series-connected memory cells (e.g., non-volatile memory cells), such as one of strings 206₀ to 206_{M}. Each string 206 can be connected (e.g., selectively connected) to a source line 216 (SRC) and can include memory cells 208₀ to 208_{N}. The memory cells 208 of each string 206 can be connected in series between a select gate 210, such as one of the select gates 210₀ to 210_{M}, and a select gate 212, such as one of the select gates 212₀ to 212_{M}. In some embodiments, the select gates 210₀ to 210_{M} are source-side select gates (SGS) and the select gates 212₀ to 212_{M} are drain-side select gates. Select gates 210₀ to 210_{M} can be connected to a select line 214 (e.g., source-side select line) and select gates 212₀ to 212_{M} can be connected to a select line 215 (e.g., drain-side select line). The select gates 210 and 212 might represent a plurality of select gates connected in series, with each select gate in series configured to receive a same or independent control signal. A source of each select gate 210 can be connected to SRC 216, and a drain of each select gate 210 can be connected to a memory cell 208₀ of the corresponding string 206. Therefore, each select gate 210 can be configured to selectively connect a corresponding string 206 to SRC 216. A control gate of each select gate 210 can be connected to select line 214. The drain of each select gate 212 can be connected to the bitline 204 for the corresponding string 206. The source of each select gate 212 can be connected to a memory cell 208N of the corresponding string 206. Therefore, each select gate 212 might be configured to selectively connect a corresponding string 206 to the bitline 204. A control gate of each select gate 212 can be connected to select line 215.

In some embodiments, and as will be described in further detail below with reference to FIG. 2B, the memory array in FIG. 2A is a three-dimensional memory array, in which the strings 206 extend substantially perpendicular to a plane containing SRC 216 and to a plane containing a plurality of bitlines 204 that can be substantially parallel to the plane containing SRC 216.

FIG. 2B is another schematic of a portion of an array of memory cells 200B (e.g., a portion of the array of memory cells 104) arranged in a three-dimensional memory array structure. The memory array 200B may incorporate vertical structures which may include semiconductor pillars where a portion of a pillar may act as a channel region of the memory cells of strings 206. The strings 206 may be each selectively connected to a bit line 204₀-204_{M} by a select gate 212 and to the SRC 216 by a select gate 210. Multiple strings 206 can be selectively connected to the same bitline 204. Groups of strings 206 can be connected to their respective bitlines 204 by biasing the select lines 215₀-215_{L} to selectively activate particular select gates 212 each between a string 206 and a bitline 204. The select gates 210 can be activated by biasing the select line 214. Each wordline 202 may be connected to multiple rows of memory cells of the memory array 200B. Rows of memory cells that are commonly addressable by each other by a particular wordline 202 may collectively be referred to as tiers.

FIG. 2C is a diagram of a portion of an array of memory cells 200C (e.g., a portion of the array of memory cells 104). Channel regions (e.g., semiconductor pillars) 238 represent the channel regions of different strings of series-connected memory cells (e.g., strings 206 of FIGS. 2A-2B) selectively connected to the bitline 204₀ and/or bitline 204₁. A memory cell (not depicted in FIG. 2C) may be formed at each intersection of a wordline 202 and one of the channel regions 238, and the memory cells corresponding to one of the channel regions 238 may collectively form a string of series-connected memory cells (e.g., a string 206 of FIGS. 2A-2B). Additional features might be common in such structures, such as dummy wordlines, blocked channel regions with interposed conductive regions, etc.

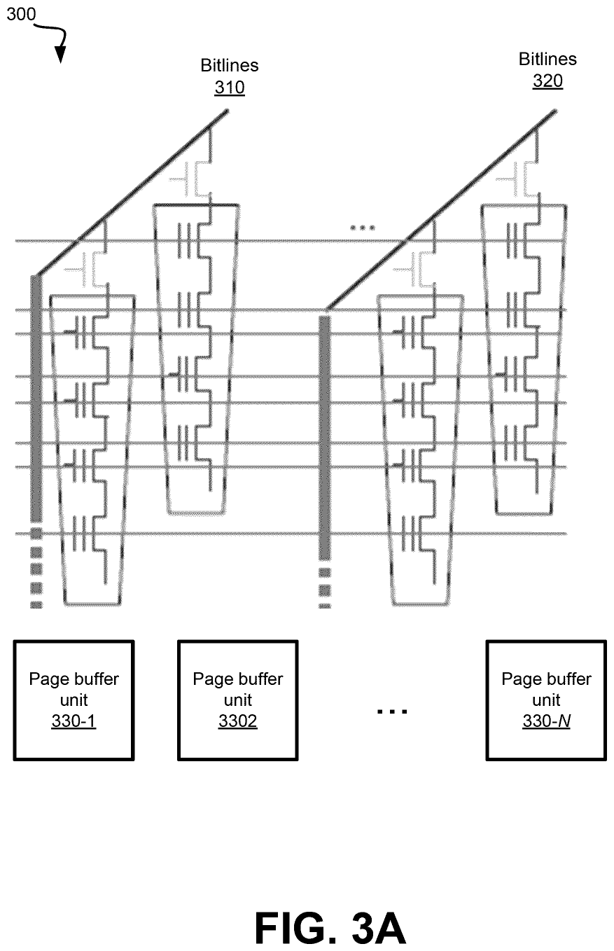

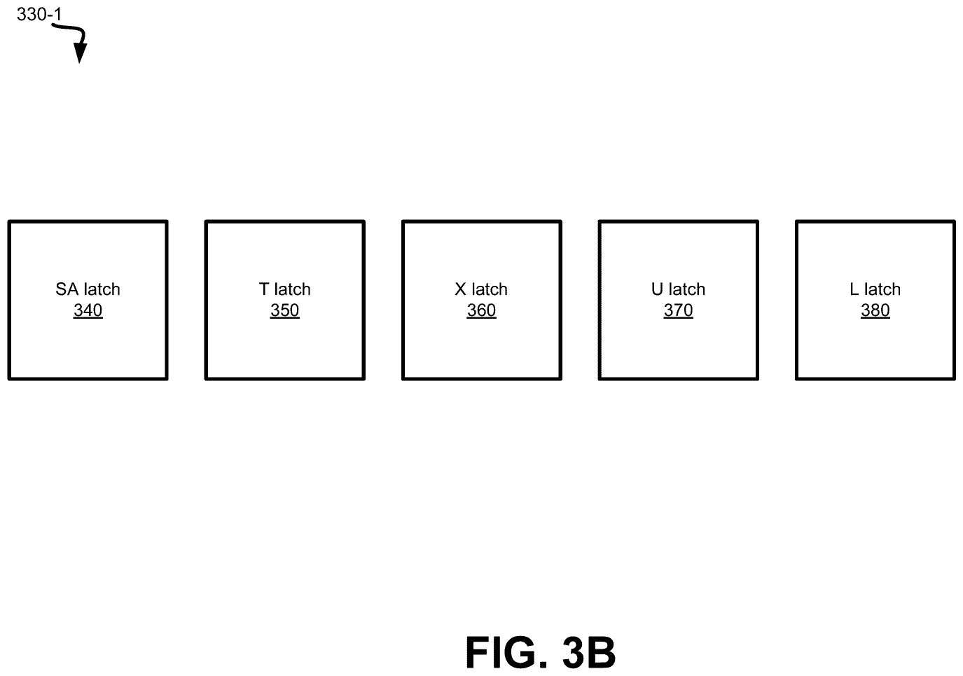

FIG. 3A is a diagram of a system 300 for implementing memory device program inhibit operations with target level selection, in accordance with some embodiments of the present disclosure. As shown, the system 300 includes a set of bitlines 310 and a set of bitlines 320. The set of bitlines 310 can include m bitlines and the set of bitlines 320 can include n bitlines. The system 300 can further include a set of page buffer units 330-1 through 330-N.

For a particular program loop, a controller (e.g., local media controller 135 of FIGS. 1A-1B) can use the set of page buffer units 330-1 through 330-N to select a (proper) subset of program levels of a set of remaining program levels to be programmed. The subset of program levels can include a number of consecutive program levels. The number of consecutive program levels of the subset of program levels (i.e., the cardinality of the subset of program levels) can be less than or equal to a maximum number of program levels that can be programmed during a program loop, where the maximum number of program levels that can be programmed during the program loop is less than the total number of remaining program levels to be programmed (i.e., the cardinality of the set of remaining program levels). In some embodiments, the number of consecutive program levels is two (e.g., L1 and L2). In some embodiments, the number of consecutive program levels is three (e.g., L1, L2 and L3). Visually, and as will be described below with reference to FIG. 4, the subsets across the program loops illustrate a diagonal programming “band” surrounded by inhibited levels.

As an illustrative example, for a QLC device having 16 levels including erase level L0 and program levels L1-15, assume that the maximum number of program levels that can be programmed during the program loop is two. During the first program loop, levels L1 and L2 can be programmed together, while an inhibit bias voltage can be applied to the bitlines corresponding to levels L0 and L3-L15. During the second program loop, levels L2 and L3 can be programmed together, while an inhibit bias voltage is applied to the bitlines corresponding to levels L0, L1 and L4-L15. During the third program loop, levels L3 and LA can be programmed together, while an inhibit bias voltage is applied to the bitlines corresponding to levels L0, L1, L2, and L5-L15. A similar process can continue until the last final program loop. Thus, the number of inhibited bitlines remains approximately constant from the first program loop to the last program loop.

During a particular program loop, the controller can cause a ground voltage to be applied to the set of bitlines 310 in order to apply a ground voltage to cells connected to the set of bitlines 310 during the program loop, and can cause an inhibit bias voltage can be applied to the set of bitlines 320 in order to inhibit the cells connected to the set of bitlines 320 from being programmed by the ground voltage during the program loop. As will be described in further detail below with reference to FIG. 3B, the set of page buffer units 330-1 through 330-N can store bits to control, for the program loop, application of the inhibit bias voltage to the set of bitlines 320 for inhibiting cells connected to those bitlines, and application of the ground voltage to the set of bitlines 310 for programming cells connected to the set of bitlines 310.

FIG. 3B is a diagram of an example page buffer unit 330-1, in accordance with some embodiments of the present disclosure. The page buffer unit 330-1 can include multiple latches. For example, as shown, the page buffer unit 330-1 can include a sense amplifier (SA) latch 340, a “T” latch 350, an “X” latch 360, a “U” latch 370, and an “L” latch 380. In some embodiments, at least one of the latches is implemented by a primary data cache (PDC). Each of the latches can store a bit value, and combinational logic can be used to control, for each program loop, application of the inhibit bias voltage to certain bitlines (e.g., the set of bitlines 320) for inhibiting cells connected to those bitlines, and application of the ground voltage to target bitlines (e.g., the set of bitlines 310) for programming cells connected to those target bitlines. In some embodiments, a bit value of 0 stored in the SA latch 340 for each target program level selected for programming during a program loop. An illustrative example of implementing memory device program inhibit operations with target level selection will now be described below with reference to FIG. 4.

FIG. 4 is as diagram 400 illustrating an example of implementing memory device program inhibit operations with target level selection, in accordance with some embodiments of the present disclosure. In this illustrative example, the subset of program levels includes two levels, such that two program levels are programmed during each program loop. There are M total program loops.

As shown, during the first program loop (“Loop 1”), program levels L1 and L2 are selected to be programmed. An inhibit bias voltage is applied to a first set of bitlines corresponding to the erase level L0, and a second set of bitlines corresponding to the program levels L3-L15, while a ground voltage is applied to the cells connected to the bitlines corresponding to program levels L1 and L2.

During the next program loop (“Loop 2”), program levels L2 and L3 are selected to be programmed. An inhibit bias voltage is applied to a first set of bitlines corresponding to the erase level L0 and program level L1, and a second set of bitlines corresponding to the program levels L4-L15, while a ground voltage is applied to the cells connected to the bitlines corresponding to program levels L2 and L3. The process continues as such until Loop M-1. During Loop M-1, only program level L15 is selected to be programmed (since program level L14 was completed during the previous loop, Loop M-2). An inhibit bias voltage is applied to a first set of bitlines corresponding to the erase level L0 and program levels L1-L14, while a ground voltage is applied to the cells connected to the bitlines corresponding to program level L15.

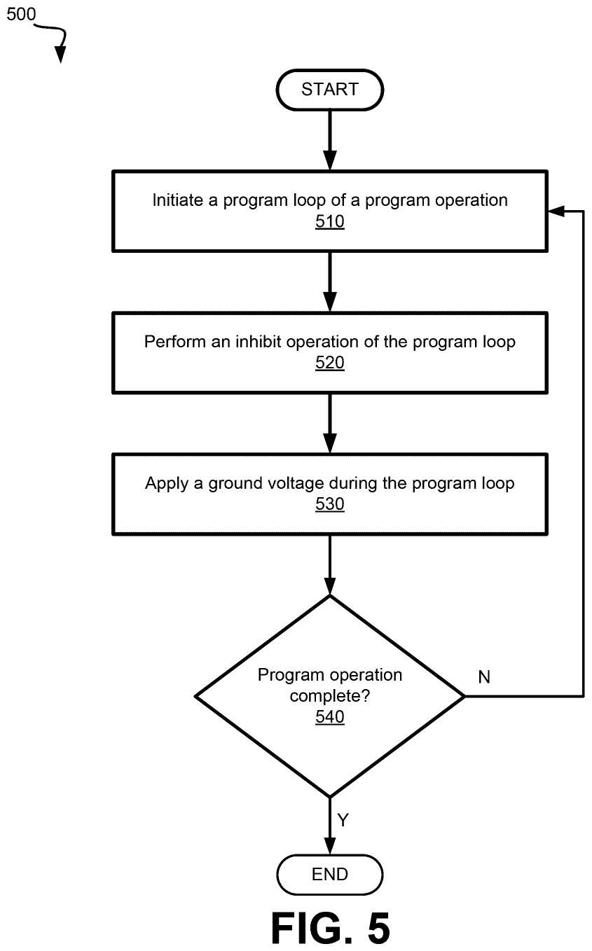

FIG. 5 is a flow diagram of a method to implementing memory device program inhibit operations with target level selection, in accordance with some embodiments of the present disclosure. The method 500 can be performed by control logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 500 is performed by the TPC 137 of FIGS. 1A-1B. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 510, a program loop of a program operation is initiated. For example, control logic can cause the program loop to be initiated. Causing the program loop to be initiated can include selecting a first group of bitlines corresponding to target program levels to be programmed during the program loop, and a second group of bitlines corresponding to the program levels that are to be inhibited during the program loop (e.g., the erase level, any program levels that have already been programmed, and any program levels that have not yet been programmed and are not included in the target program levels).

The target program levels can include a number of consecutive program levels that can be programmed during a program loop. The number of consecutive program levels that can be programmed during the program loop can be less than or equal to a maximum number of program levels that can be programmed during the program loop, where the maximum number of program levels that can be programmed during the program loop is less than the total number of remaining program levels to be programmed. The target program levels can include at least two consecutive program levels. In some embodiments, the maximum number is two (e.g., up to two consecutive program levels can be programmed during the program loop). In some embodiments, the target program levels include three consecutive program levels (e.g., up to three consecutive program levels can be programmed during the program loop). The number of target program levels selected during each program loop should not be considered limiting.

At operation 520, an inhibit operation of the program loop is performed. For example, control logic can cause an inhibit bias voltage to be applied to the second group of bitlines in order to perform the inhibit operation.

At operation 530, a ground voltage is applied during the program loop. For example, control logic can cause the ground voltage to be applied to the first group of bitlines corresponding to the target program levels. The memory array can be operatively coupled to a set of page buffer units defining the first group of wordlines and the second group of wordlines. For example, each page buffer unit comprises a plurality of latches.

At operation 540, it is determined whether the program operation is complete. If not, this means that there are additional program levels that have not been programmed yet, and the process reverts back to operation 510 to initiate the next program loop of the program operation. Otherwise, if the program operation is complete, this means that process ends.

In some embodiments, the memory device is a QLC (memory) device. As an illustrative example, for a QLC device having 16 levels including erase level L0 and program levels L1-15, assume that the maximum number of program levels that can be programmed during the program loop is two. During the first program loop, levels L1 and L2 can be programmed together, while an inhibit bias voltage will be applied to the bitlines corresponding to levels L0 and L3-L15. During the second program loop, levels L2 and L3 can be programmed together, while an inhibit bias voltage is applied to the bitlines corresponding to levels L0, L1 and L4-L15. During the third program loop, levels L3 and LA can be programmed together, while an inhibit bias voltage is applied to the bitlines corresponding to levels L0, L1, L2, and L5-L15. A similar process can continue until the last final program loop. Thus, the number of inhibited bitlines remains approximately constant from the first program loop to the last program loop. Further details regarding operations 510-540 are described above with reference to FIGS. 3A-4.

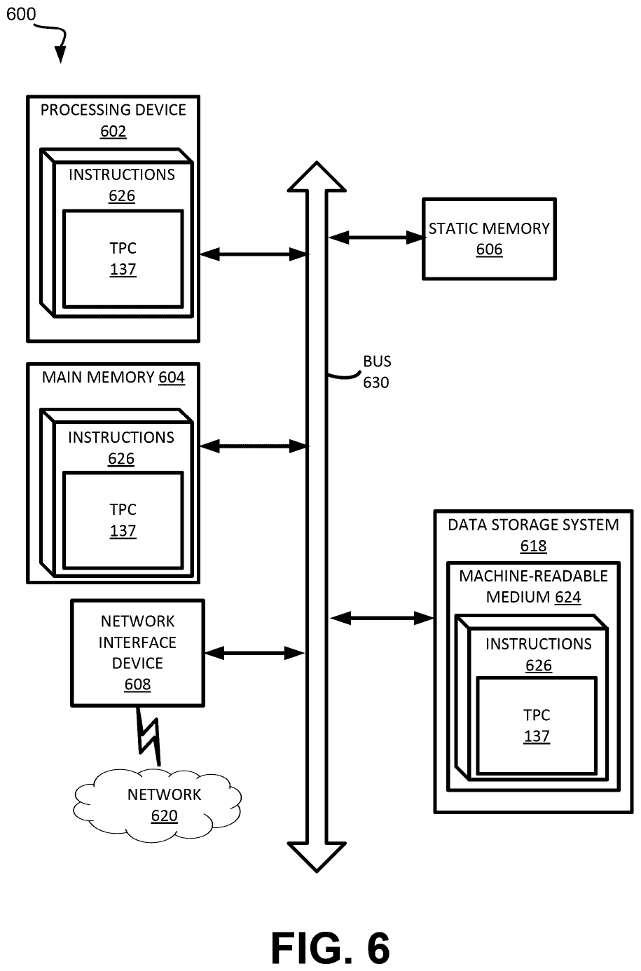

FIG. 6 illustrates an example machine of a computer system 600 within which a set of instructions, for causing the machine to perform any one or more of the methodologies discussed herein, can be executed. In some embodiments, the computer system 600 can correspond to a host system (e.g., the host system 120 of FIG. 1) that includes, is coupled to, or utilizes a memory sub-system (e.g., the memory sub-system 110 of FIG. 1) or can be used to perform the operations of a controller (e.g., to execute an operating system to perform operations corresponding to the TPC 137 of FIG. 1). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The computer system 600 includes a processing device 602, a main memory 604 (e.g., read-only memory (ROM), flash memory, dynamic random access memory (DRAM) such as synchronous DRAM (SDRAM) or RDRAM, etc.), a static memory 606 (e.g., flash memory, static random access memory (SRAM), etc.), and a data storage system 618, which communicate with each other via a bus 630.

Processing device 602 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 602 can also be one or more special-purpose processing devices such as an application specific integrated circuit (ASIC), a field programmable gate array (FPGA), a digital signal processor (DSP), network processor, or the like. The processing device 602 is configured to execute instructions 626 for performing the operations and steps discussed herein. The computer system 600 can further include a network interface device 508 to communicate over the network 620.

The data storage system 618 can include a machine-readable storage medium 624 (also known as a computer-readable medium) on which is stored one or more sets of instructions 626 or software embodying any one or more of the methodologies or functions described herein. The instructions 626 can also reside, completely or at least partially, within the main memory 604 and/or within the processing device 602 during execution thereof by the computer system 600, the main memory 604 and the processing device 602 also constituting machine-readable storage media. The machine-readable storage medium 624, data storage system 618, and/or main memory 604 can correspond to the memory sub-system 110 of FIG. 1.

In one embodiment, the instructions 626 include instructions to implement functionality corresponding to an EV component (e.g., the EV component 137 of FIG. 1). While the machine-readable storage medium 624 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sen'se rather than a restrictive sense.

What is claimed is:

1. A memory device comprising:
a memory array; and
control logic, operatively coupled with the memory array, to perform operations comprising:
selecting a first group of bitlines of the memory array, the first group of bitlines corresponding to target program levels to be programmed during a program loop;
selecting a second group of bitlines of the memory array, the second group of bitlines corresponding to program levels that are to be inhibited during the program loop, wherein the second group of bitlines comprises at least one bitline corresponding to a program level that has not been programmed;
causing an inhibit bias voltage to be applied to the second group of bitlines; and
causing a ground voltage to be applied to program the first group of bitlines during the program loop.

2. The memory device of claim 1, wherein the target program levels to be programmed during the program loop comprise at least two consecutive program levels.

3. The memory device of claim 2, wherein a number of consecutive program levels is less than or equal to a maximum number of program levels that can be programmed during the program loop, and wherein the maximum number of program levels is less than a total number of remaining program levels to be programmed.

4. The memory device of claim 1, wherein causing the ground voltage to be applied to the first group of bitlines further comprises applying a ground voltage to the first group of bitlines.

5. The memory device of claim 1, wherein the memory device is a quad-level cell (QLC) memory device.

6. The memory device of claim 1, wherein the memory array is operatively coupled to a set of page buffer units defining the first group of bitlines and the second group of bitlines.

7. The memory device of claim 6, wherein each page buffer unit comprises a plurality of latches.

8. A method comprising:
selecting a first group of bitlines associated with a memory array of a memory device, the first group of bitlines corresponding to target program levels to be programmed during a program loop;
selecting a second group of bitlines associated with the memory array, the second group of bitlines corresponding to program levels that are to be inhibited during the program loop, wherein the second group of bitlines comprises at least one bitline corresponding to a program level that has not been programmed;
causing an inhibit bias voltage to be applied to the second group of bitlines; and
causing a ground voltage to be applied to program the first group of bitlines during the program loop.

9. The method of claim 8, wherein the target program levels to be programmed during the program loop comprise at least two consecutive program levels.

10. The method of claim 9, wherein a number of consecutive program levels is less than or equal to a maximum number of program levels that can be programmed during the program loop, and wherein the maximum number of program levels is less than a total number of remaining program levels to be programmed.

11. The method of claim 8, wherein causing the ground voltage to be applied to the first group of bitlines further comprises applying a ground voltage to the first group of bitlines.

12. The method of claim 8, wherein the memory device is a quad-level cell (QLC) memory device.

13. The method of claim 8, wherein the memory array is operatively coupled to a set of page buffer units defining the first group of bitlines and the second group of bitlines.

14. The method of claim 13, wherein each page buffer unit comprises a plurality of latches.

15. A non-transitory computer-readable storage medium comprising instructions that, when executed by a processing device, cause the processing device to perform operations comprising:
selecting a first group of bitlines associated with a memory array of a memory device, the first group of bitlines corresponding to target program levels to be programmed during a program loop;
selecting a second group of bitlines associated with the memory array, the second group of bitlines corresponding to program levels that are to be inhibited during the program loop, wherein the second group of bitlines comprises at least one bitline corresponding to a program level that has not been programmed;
causing an inhibit bias voltage to be applied to the second group of bitlines; and
causing a ground voltage to be applied to program the first group of bitlines during the program loop.

16. The non-transitory computer-readable storage medium of claim 15, wherein the target program levels to be programmed during the program loop comprise at least two consecutive program levels.

17. The non-transitory computer-readable storage medium of claim 16, wherein a number of consecutive program levels is less than or equal to a maximum number of program levels that can be programmed during the program loop, and wherein the maximum number of program levels is less than a total number of remaining program levels to be programmed.

18. The non-transitory computer-readable storage medium of claim 15, wherein causing the ground voltage to be applied to the first group of bitlines further comprises applying a ground voltage to the first group of bitlines.

19. The non-transitory computer-readable storage medium of claim 15, wherein the memory device is a quad-level cell (QLC) memory device.

20. The non-transitory computer-readable storage medium of claim 15, wherein the memory array is operatively coupled to a set of page buffer units defining the first group of bitlines and the second group of bitlines, and wherein each page buffer unit comprises a plurality of latches.
